(19) United States
(12) Patent Application Publication
(10) Pub. No.: US 2008/0088030 A1
(43) Pub. Date: Apr. 17, 2008

(54) ATTACHING AND INTERCONNECTING DIES TO A SUBSTRATE

(75) Inventors: Benjamin N. Eldridge, Danville, CA (US); Igor Y. Khandros, Orinda, CA (US); Charles A. Miller, Fremont, CA (US)

Correspondence Address: N. KENNETH BURRASTON;KIRTON & MCCONKIE, P.O. BOX 45120, SALT LAKE CITY, UT, 84145-0120, US

(73) Assignee: FORMFACTOR, INC.

(21) Appl. No.: 11/863,443

(22) Filed: Sep. 28, 2007

Related U.S. Application Data
(60) Provisional application No. 60/829,675, filed on Oct. 16, 2006.

(51) Int. Cl. H01L 23/48; H01L 21/66

(52) U.S. Cl. 257/777; 438/15; 257/E23.01; 257/E21.529

(57) ABSTRACT

An electronics module can include a wiring substrate with openings. The wiring substrate can have traces, and semiconductor dies can be attached by a first relatively weak adhesive to the wiring substrate. Electrical connections through the openings can electrically connect the traces and the terminals. Another adhesive can more strongly adhere the dies to the wiring substrate. The electronics module can be made by a process that includes attaching the semiconductor dies to the wiring substrate with a relatively weak adhesion, electrically connecting through the openings the traces and the terminals, and more securely attaching selected ones of the dies to the wiring substrate.

### RELATED APPLICATIONS

This application claims priority to U.S. Provisional Patent Application No. 60/829,675 for METHOD OF ATTACHING AND INTERCONNECTING A BARE DIE TO A SUBSTRATE, filed on Oct. 16, 2006.

### BACKGROUND

Electronics modules comprising a plurality of electrically interconnected semiconductor dies attached to a wiring substrate are known. Such electronics modules can be digital storage electronic units, data processing electronic units, signal processing electronic units, digital control electronic units, or electronic units performing any number of functions. Typically, the dies are physically attached to the wiring substrate and electrically connected to electrically conductive paths on the wiring substrate.

Although the present invention is not limited to providing any of the advantages discussed below, some embodiments of the invention can provide advantages in the assembly, testing, and/or use of electronics modules. For example, some embodiments of the invention can simplify assembly of an electronics module. As another example, some embodiments of the invention can simplify testing an electronics module by, for example, facilitating removal of a die or dies that caused the module to fail the testing and replacement of the failed die or dies with a new die or dies. As yet another example, some embodiments of the invention can accommodate different rates of thermal expansion or contraction of the dies, on one hand, and the wiring substrate, on the other hand. Such different rates of thermal expansion or contraction can occur where the dies comprise a material or materials with one coefficient of thermal expansion and the wiring substrate comprises a material or materials with a different coefficient of thermal expansion. Embodiments of the invention can provide the foregoing as well as other advantages.

### BRIEF DESCRIPTION OF THE DRAWINGS

FIG. 1A shows a top view of an exemplary electronics module according to some embodiments of the invention.

FIG. 1B shows a side, cross-sectional view of the electronics module of FIG. 1A.

FIG. 2 illustrates an exemplary process that can be used to make an electronics module like the electronics module of FIG. 1 A according to some embodiments of the invention.

FIG. 3 illustrates a top view of an exemplary wiring substrate according to some embodiments of the invention.

FIG. 4A illustrates a partial, bottom view of the wiring substrate of FIG. 3 with an added dam.

FIG. 4B shows a side, cross-sectional view of the electronics module of FIG. 4A.

FIG. 5A illustrates a partial, bottom view of the wiring substrate of FIGS. 4A and 4B with an attached die.

FIG. 5B shows a side, cross-sectional view of the electronics module of FIG. 5A.

FIG. 6A illustrates a partial, top view of the wiring substrate of FIGS. 5A and 5B with electrical connections between traces and die terminals.

FIG. 6B shows a side, cross-sectional view of the electronics module of FIG. 6A.

FIG. 7A illustrates a partial, top view of the wiring substrate of FIG. 6A and 6B with addition of an adhesive.

FIG. 7B illustrates a bottom view of the wiring substrate of FIG. 7A.

FIG. 7C shows a side, cross-sectional view of the electronics module of FIGS. 7A and 7B.

FIG. 8 illustrates a side, cross-sectional view of another electronics module according to some embodiments of the invention.

FIG. 9 illustrates a partial, side, cross-sectional view of the electronics module of FIG. 8 illustrating exemplary attachment of dies to a wiring substrate.

FIG. 10 illustrates a partial, top view of yet another exemplary electronics module according to some embodiments of the invention.

FIG. 11 illustrates a side, cross-sectional view of the electronics module of FIG. 10.

### DETAILED DESCRIPTION OF EXEMPLARY EMBODIMENTS

This specification describes exemplary embodiments and applications of the invention. The invention, however, is not limited to these exemplary embodiments and applications or to the manner in which the exemplary embodiments and applications operate or are described herein. Moreover, the Figures may show simplified or partial views, and the dimensions of elements in the Figures may be exaggerated or otherwise not in proportion for clarity. In addition, as the terms “on” and “attached to” are used herein, one object (e.g., a material, a layer, a substrate, etc.) can be “on” or “attached to” another object regardless of whether the one object is directly on or attached to the other object or there are one or more intervening objects between the one object and the other object. Also, directions (e.g., above, below, top, bottom, side, up, down “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

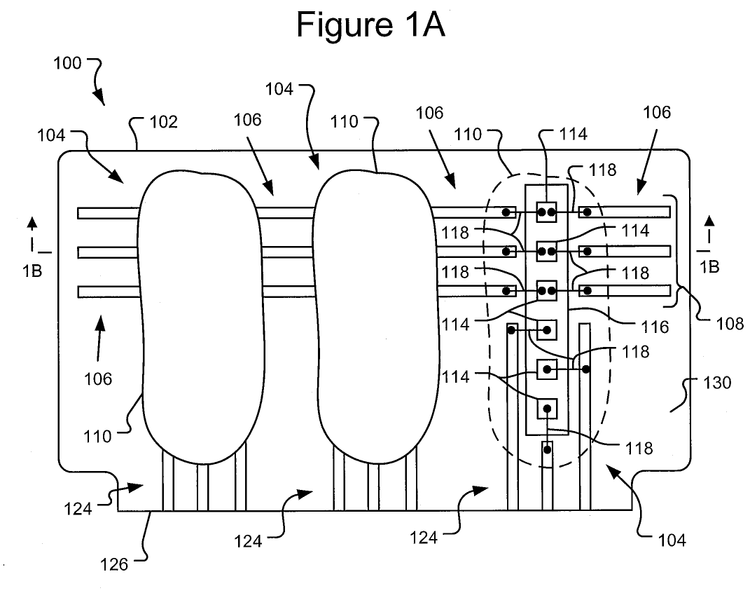

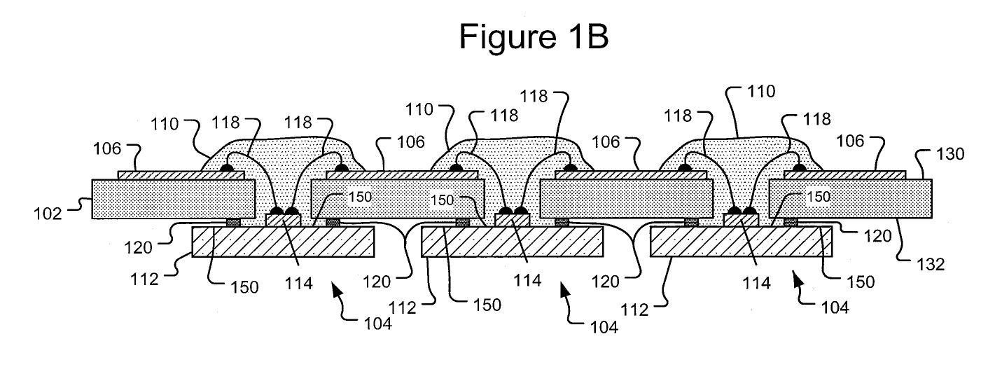

FIGS. 1A and 1B illustrate an exemplary electronics module 100 according to some embodiments of the invention. As shown, the electronics module 100 can include a wiring substrate 102 with a plurality of first traces 106 and a plurality of second traces 124 disposed on a first surface 130 (which can be a non-limiting example of a layer) of the wiring substrate 102. (Traces 106 and/or 124 on the wiring substrate 102 can be examples of first traces.) Semiconductor dies 112 can be attached to a second surface 132 (which can be a non-limiting example of a surface of wiring substrate 102) of the wiring substrate 102 such that terminals 114 of the dies 112 are disposed in or accessible through openings 116 in the wiring substrate 102. Electrical connections 118 can be made between ones of the first traces 106 and the second traces 124, on one hand, and ones of the terminals 114 of the dies 112, on the other hand. Although not shown, electrical connections 118 can also be made directly between traces (e.g., between one of the first traces 106 and another of the first traces 106 or one of the second traces 124). As shown, the electrical connections 118 to ones of the terminals 114 of the dies 112 can be made through the openings 116. An adhesive material 110 can be deposited into the openings 116 and can adhere a die 112 to the wiring substrate 102. (Adhesive material 110 can be a non-limiting example of a flowable adhesive, a second adhesive, and/or attaching a die 112 to the second surface of wiring substrate 102 with a relatively strong or second adhesive strength that is stronger than a first adhesive strength.) As also shown, a material can be disposed between the wiring substrate 102 and die surface 150 of a die 112 to form a dam structure 120 that can limit the flow of the adhesive material 110 and thus limit the surface area on a die 112 onto which the adhesive material 110 flows. The adhesive material 110 can form a rigid (e.g., substantially non-compliant) joint between a die 112 and the wiring substrate 102. Alternatively, the adhesive material 110 can comprise a material that forms a compliant joint between the die 112 and the wiring substrate 102. Thus, the bond between a die 112 and the wiring substrate 102 can be rigid (e.g., allowing substantially no appreciable movement between the die 112 and the wiring substrate 102 without substantial damage to the die 112, the wiring substrate 102, or the bond), or alternatively, the bond between a die 112 and the wiring substrate 102 can be compliant (e.g., allowing appreciable movement between the die 112 and the wiring substrate 102 without substantial damage to the die 112, the wiring substrate 102, or the bond). Regardless, the adhesive material 110 can overfill the opening 116 and envelope electrical connections 118 to strengthen, cover, and/or protect the electrical connections 118.

The wiring substrate 102 can be any substrate suitable for supporting a plurality of electrically conductive traces (e.g., like first traces 106 and second traces 124). For example, wiring substrate 102 can comprise a printed circuit board. As another example, wiring substrate 102 can comprise a flexible material. The first traces 106 and the second traces 124 can comprise electrically conductive material deposited or formed on the first surface 130 of the wiring substrate 102. Although not shown, additional such traces can be disposed on the first surface 130 and/or the second surface 132 of the wiring substrate 102 and/or within the wiring substrate 102, which can comprise multiple layers of such traces. In addition, electronic elements (not shown), such as passive electronic elements (e.g., resistors, capacitors, etc.) can be attached to wiring substrate 802.

Each die 112 along with the dam structure 120, adhesive material 110, and electrical connections 118 that connect terminals 114 of the die 112 to ones of the traces 106, 124 can be said to form a die attachment structure 104. Shown in FIGS. 1A and 1B are three die attachment structures 104, although more or fewer can be included in other configurations of the electronics module 100. Note that the right-most die attachment structure 104 in FIG. 1A is shown with the adhesive material 110 in dashed lines so that ones of the traces 106 and/or 124, terminals 114, and electrical connections 118 are visible in FIG. 1A.

The first traces 106 can be disposed in a pattern and electrically connected to terminals 114 of the dies 112 to form a data bus structure 108. For example, the left most die attachment structure 104 and the middle die attachment structure 104, although not visible in FIG. 1A due to adhesive material 110, can have the configuration shown in the right most die attachment structure 104 in which electrical connectors 1 18 electrically connect a first trace 106 on one side of an opening 116, to a terminal 114, and to another first trace 106 on another side of the opening 116. First traces 106 can thus form a bus structure 108 electrically connecting ones of the terminals of each of the dies 112. Alternatively, a connection to a terminal 114 of a die 112 can be bypassed by providing an electrical connection 118 that extends from one of the first traces 106 on one side of an opening 116 to another of the first traces 106 on another side of the opening 116 without contacting a terminal 114. The traces 106, 124 (and other electronic connectors (not shown)) can be configured to have impedances tailored to desired levels of impedance.

The wiring substrate 102 can include an edge connection portion 126 configured to make electrical connections with another wiring substrate (not shown), an electrical socket (not shown), or any other type of electrical device (not shown). The second traces 124 can be disposed in a pattern in which the second traces 124 extend to the edge connection portion 126. Other traces (not shown) on the first surface 130 of the wiring substrate 102 or disposed on the second surface 132 of the wiring substrate 102 or within the wiring substrate 102 can be provided from the edge connection portion 126 to ones of the first traces 106, and the bus structure 108 can thus be electrically connected to connections on the edge connector portion 126.

The dies 112 can be any type of semiconductor die. For example, the dies 112 can comprise digital memory circuitry, processor circuitry, digital circuitry, analog circuitry, etc. The dies 112 can be bare and unpackaged, and the terminals 114 can be the native bond pads of the dies 112. Alternatively, the dies can comprise packaging, and the terminals 114 can be electrically conductive interconnect structures that are electrically connected to native bond pads of the dies 112. The electrical connections 118 can comprise electrical wires bonded (e.g., using standard wire bonding techniques) to terminals 114 and traces 106, 124. Alternatively, the electrical connections 118 can comprise other forms of electrical connections (e.g., a lead frame). The terminals 114 need not be the same size, nor do the terminals 114 need to be disposed in a line. Rather, terminals 114 can be any size and disposed in any pattern on a die 112.

The adhesive material 110 can be any type of adhesive material suitable for adhering a die 112 to a wiring substrate 102. The adhesive material 110 can comprise a material that is flowable when applied and thereafter hardens (e.g., in reaction to ambient air, by a curing process, etc.) Non-limiting examples of suitable adhesive materials 110 include epoxies. The dam structure 120 can comprise any material suitable for providing a barrier that impedes the flow of the adhesive material 110 and thus limits the surface area of the die 112 onto which the adhesive material 110 can flow. In some embodiments, the dam structure 120 can comprise a material that has adhesive properties. (The dam structure 120 can be a non-limiting example of a first adhesive material and/or attaching a die 112 to the second surface 132 of wiring substrate 102 with a first adhesive strength that is not as strong as a second adhesive strength.) For example, the dam structure 120 can comprise an epoxy material. Another example of a dam structure 120 is a gasket structure that is applied to the wiring substrate 102 and/or a die 112.

The electronics module 100 illustrated in FIGS. 1A and 1B is exemplary only and many variations are possible. For example, more or fewer dies 112 can be attached to the wiring substrate 102. As another example, more or fewer of the traces 106, 124 can be included, and the traces 106, 124 can be disposed in different patterns. As another example, the amount of adhesive material 110 disposed into an opening 116 shown in FIGS. 1A and 1B is exemplary only and more or less adhesive material 110 can be disposed into an opening 116. For example, less adhesive material 110 can be disposed in an opening 116 so that the opening 116 is filled but not to overflowing. As another example, the amount of adhesive material 110 disposed into an opening 116 can be sufficient only to fill space between the second side 132 of the wiring substrate 102 and a die 112 as limited by a dam structure 120. As still another example, the dam structure 120 can be replaced with dots or droplets of material (which can have adhesive properties and can thus be a non-limiting example of a first adhesive material or attaching a die 112 to the second surface 132 of wiring substrate 102 with a relatively weak or first adhesive strength that is not as strong as a second adhesive strength) that are spaced apart from each other or in other patterns that include spaces. In such a case, the flow of adhesive material 110 over a die 112 can be controlled by means other than a dam structure. For example, as will be discussed below, the flow of adhesive material 110 over the die 112 can be controlled and limited by controlling the amount of adhesive material 110 applied into an opening 116. The foregoing and other modifications can be made to the electronics module 100 shown in FIGS. 1A and 1B.

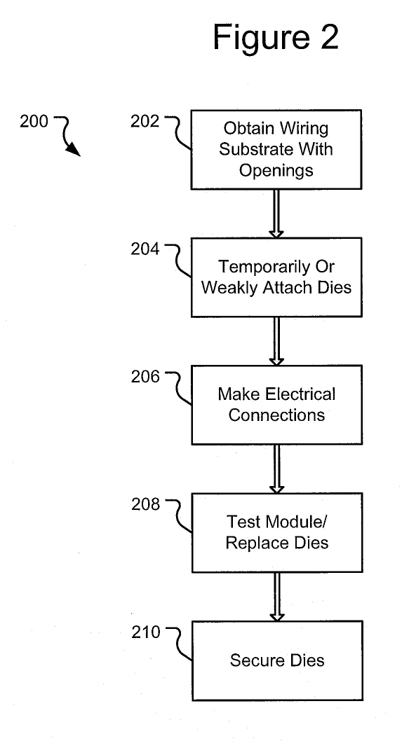

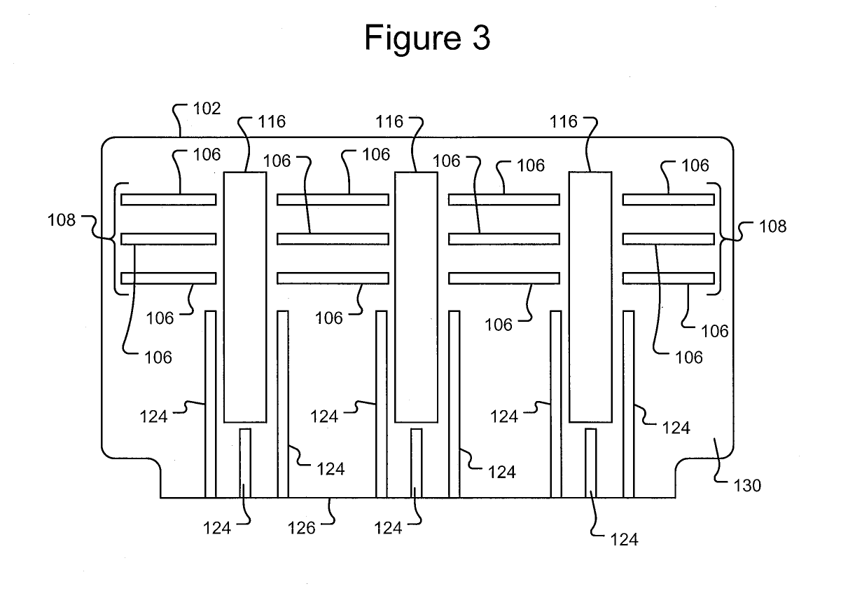

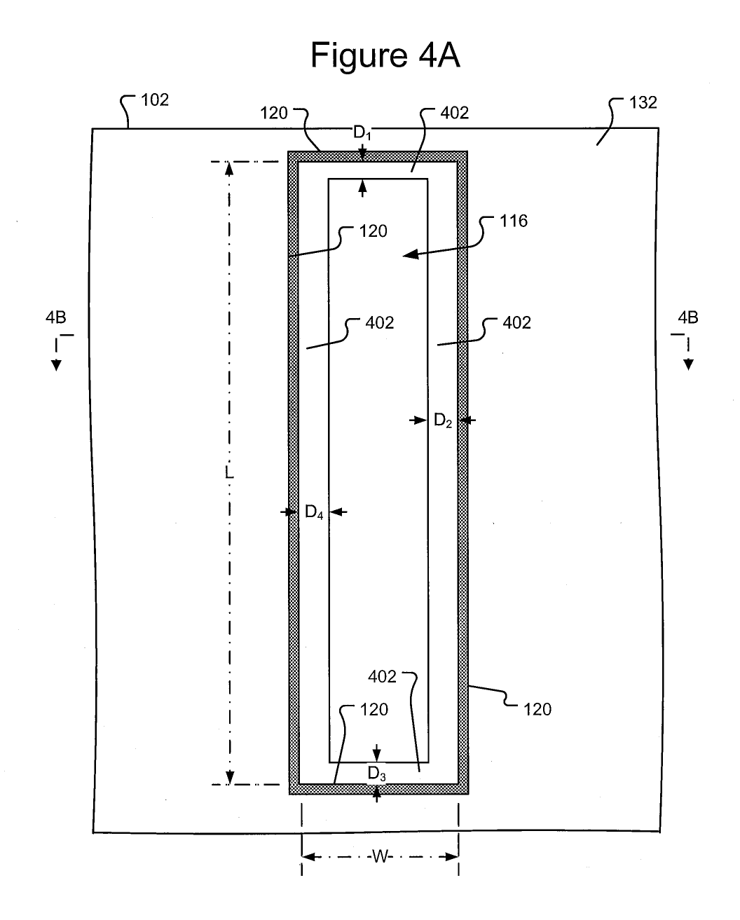

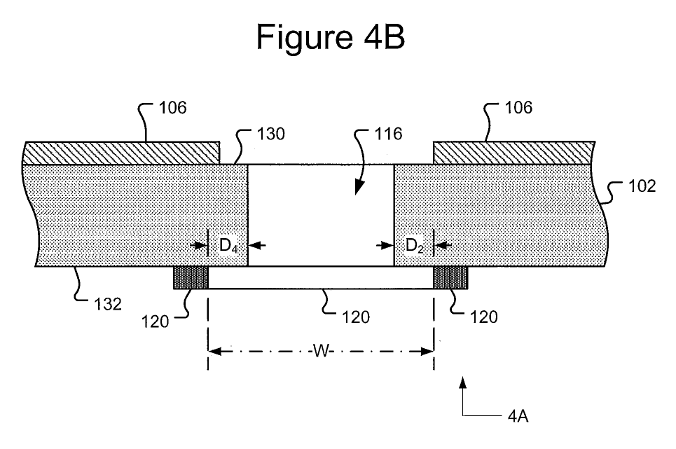

FIG. 2 shows an exemplary process 200 for making an electronics module, like electronics module 100 of FIGS. 1A and 1B according to some embodiments of the invention. Although the process 200 is not limited to making the specific electronics module 100 shown in FIGS. 1A and 1B, for purposes of illustration and ease of discussion, the process 200 is described herein in terms of making the electronics module 100 of FIGS. 1A and 1B, and FIGS. 3-7C illustrate use of the process 200 to make the electronics module 100 of FIGS. 1A and 1B. Nevertheless, the process 200 can be used to make different configurations of the electronics module 100 as well as other electronics modules. Note that, for clarity and ease of illustration, FIGS. 4A-7C show a partial view of the wiring substrate 102 and thus show only one opening 116 and one die 112. Other portions of the wiring substrate 102 including other openings 116 of the wiring substrate 102 and other dies 112 can be processed in the same way as illustrated in FIGS. 3-7C.

As shown in FIG. 2, a wiring substrate with openings 116 can be provided, obtained, or made (at 202). FIG. 3 shows an example in which the wiring substrate 102 of FIGS. 1A and 1B is obtained (at 202).

Referring again to FIG. 2, dies can be temporarily or weakly attached (e.g., attached with a first adhesive strength that is not as strong as a second adhesive strength) to the wiring substrate obtained (at 204). As shown in FIGS. 4A and 4B, this can be accomplished by creating a dam structure 120 on the second surface 132 of the wiring substrate 102 generally around each opening 116. The dam structure 120 can comprise materials like those discussed above. For example, the dam structure 120 can comprise an epoxy material. The dam structure 120 can be applied to or formed on the wiring substrate 102 in any manner suitable for applying or forming such materials on a substrate. For example, the material forming the dam structure 120 can be applied through a patterned stencil. As another example, the material forming dam structure 120 can be applied to the second surface 132 of the wiring substrate 102 and then patterned (e.g., by removing portions of the material from the second surface 132). Dam structures 120 can alternatively be applied to or formed on die surface 150 of dies 112.

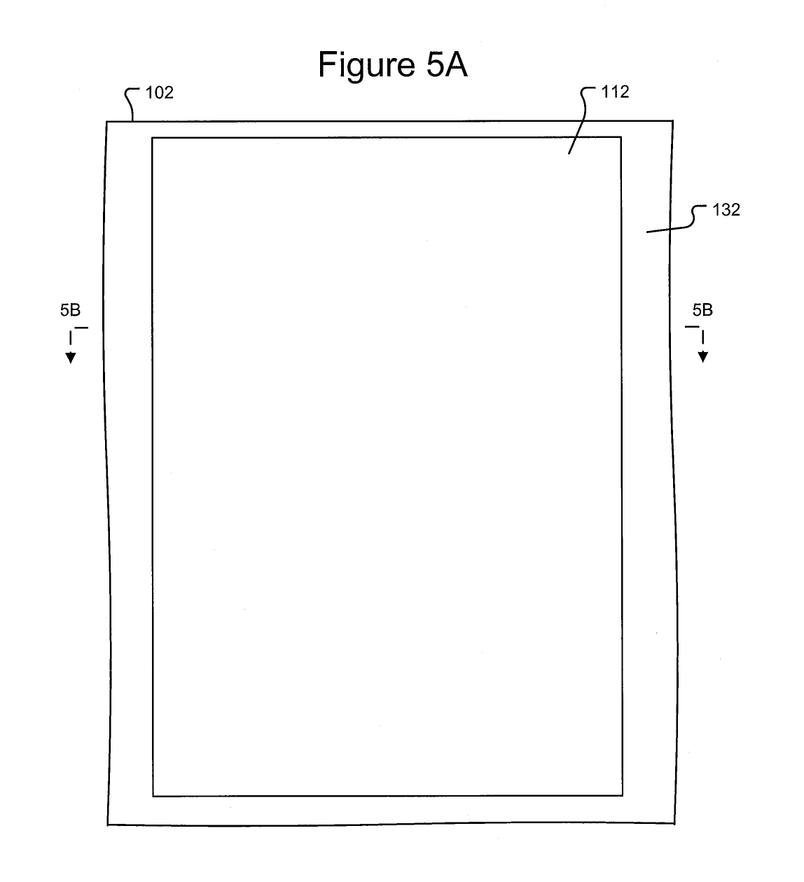

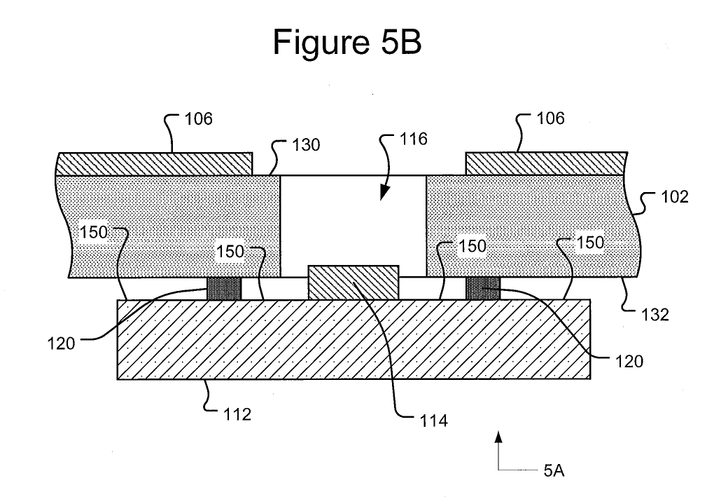

As shown in FIG. 4A, a dam structure 120 can be disposed on the second surface 132 of the wiring substrate 102 distances D₁, D₂, D₃, and D₄ from an opening 116, and a dam structure 120 can have a length L and a width W. As mentioned, alternatively, dam structures 120 can be applied to dies 112. Dam structures 120 can be applied to die surface 150 (see FIG. 5B) of a die 112, and each dam structure 120 can thus be disposed between the second surface 132 of the wiring substrate 102 and die surface 150 of a die 112. As will be discussed in more detail below, regardless of whether a dam structure 120 is applied to the wiring substrate 102 or a die 112, a dam structure 120 can limit the flow of an adhesive material 110 that will adhere the die 112 to the wiring substrate 102. Thus, the area 402 on the second surface 132 of the wiring substrate between the dam structure 120 and the opening 116 can be the only area of adhesion between a die 112 and the second surface 132 of the wiring substrate 102. Exemplary strategies for and advantages of limiting the area of adhesive between a die 112 and the wiring substrate 102 are discussed in more detail below. The shape and orientation of the area 402 shown in FIG. 4A is exemplary only, and other shapes and orientations of area 402 can be implemented. For example, area 402 need not be symmetrically oriented around opening 116.

As shown in FIGS. 5A and 5B, a die 112 can be held or pressed against the dam structure 120. If the material that forms the dam structure 120 has some adhesive properties, the dam structure 120 can hold the die 112 in place, at least weakly and/or temporarily. As shown in FIG. 5B, a die 112 can be positioned such that the terminals 114 of the die 112 are disposed in or at least accessible through an opening 116 in the wiring substrate 102. As mentioned above, rather than applying the dam structure 120 to the wiring substrate 102 and then pressing the die 112 onto the dam structure 120, the dam structure 120 can be applied to the die 112, and the dam structure 120 (attached to the die 112) can be pressed against the wiring substrate 102.

As also mentioned above, the dam structure 120 can be replaced with drops or other deposits of material that are spaced apart from each other in a pattern that thus includes spaces between the deposits. So deposited, the material would not form a dam that prevents the adhesive material 110 from flowing on the surface of a die 112. In such a case, the flow of adhesive material 110 over a die 112 can be controlled by means other than a dam structure (e.g., like dam structure 120). For example, the flow of adhesive material 110 over the die 112 can be controlled and limited by controlling the amount of adhesive material 110 deposited into an opening 116.

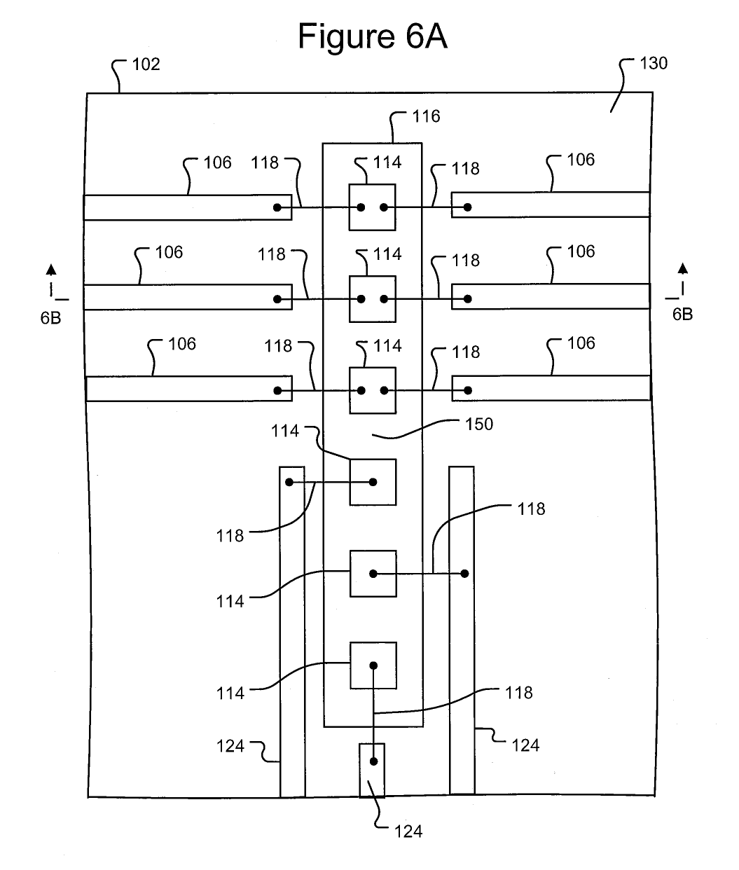

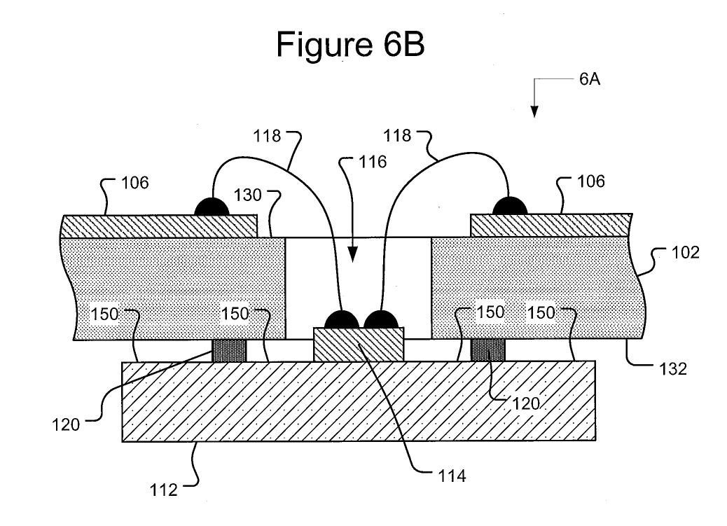

Referring again to FIG. 2, electrical connections can be made between ones of the terminals of the dies and ones of the traces on the wiring substrate (at 206). FIGS. 6A and 6B illustrate an example in which electrical connections 118 can be formed between ones of the first traces 106 and ones of the terminals 114 of the die 112, and electrical connections 118 can be formed between ones of the second traces 124 and ones of the terminals 114 of the die 112. Although not shown, electrical connections 118 can also be formed directly between traces (e.g., between one of traces 106 and another of traces 106) and/or directly between terminals 114. As shown in FIG. 6A, electrical connections 118 can electrically connect one of the first traces 106 on one side of the opening 116 to one of the terminals 114 and to another of the traces 106 on another side of the opening 116. As discussed above, by electrically connecting ones of the traces 106 as shown in FIG. 6A, a bus structure 108 (see FIG. 1A) can be made from the first traces 106. As mentioned above, the electrical connections 118 can comprise wires bonded to the terminals 114 of the dies 112 and the traces 106, 124 using standard wiring bonding techniques.

Referring again to FIG. 2, the electronics module comprising the wiring substrate 102 obtained (at 202) and the dies 112 attached to the wiring substrate 102 (at 204) and electrically connected to the wiring substrate 102 (at 206) can be tested (at 208). Any testing apparatus and procedure suitable for testing such an electronics module can be used to perform the testing. Also (at 208), if the testing reveals that one or more of the dies 112 fails testing or is otherwise not functioning properly (hereinafter referred to as a “bad die”), the bad die or dies can be removed from the wiring substrate 102 and replaced with a new die or dies. The bad die or dies can be removed by detaching the electrical connections 118 to the bad die or dies and then removing the bad die or dies from dam structure 120 or dam structures 120 to which the bad die or dies were adhered. Because the dam structure 120 or dam structures 120 adhere the dies 112 weakly or temporarily to the wiring substrate 102, the bad die or dies can easily be removed from the dam structure 102 or dam structures 102. The new die or dies that replace the removed, bad die or dies can be attached to the wiring substrate 102 by repeating 204 of process 200, and the new die or dies can be electrically connected to the wiring substrate 102 by repeating 206 of process 200. The electronics module with the new die or dies can be retested (at 208). Any failed dies can again be replaced and the electronics module retested.

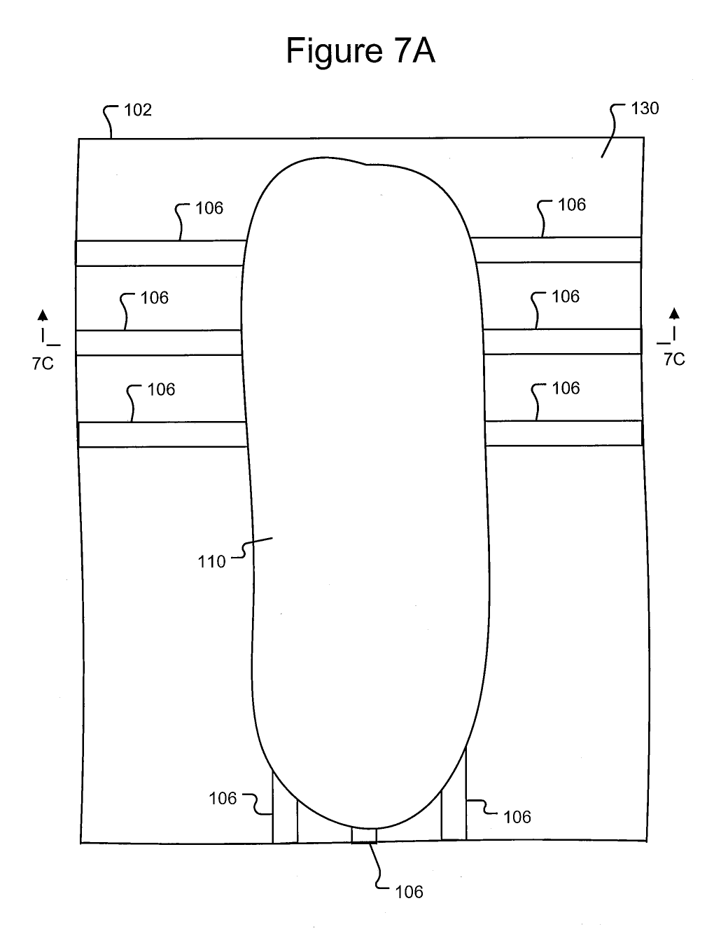

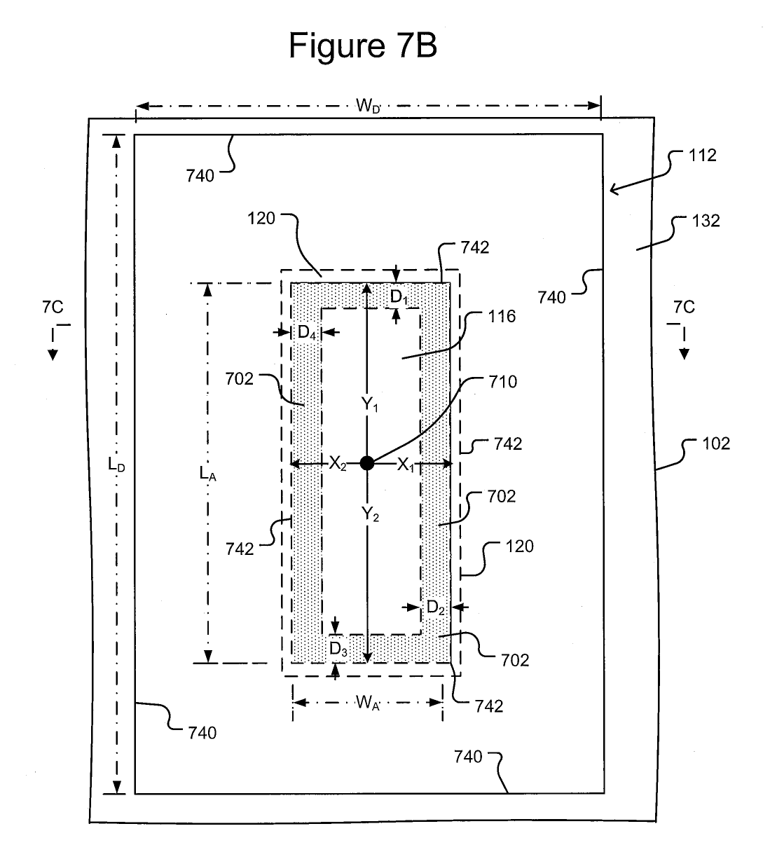

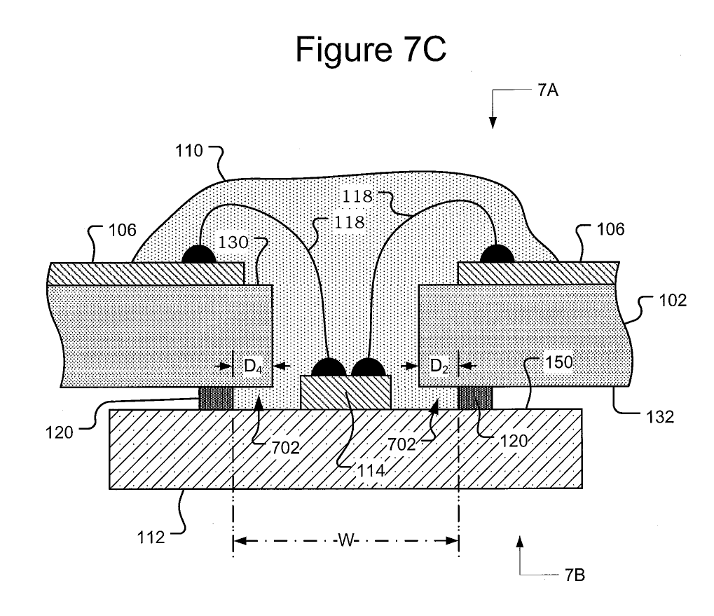

At 210, the dies 112 (including any new dies attached to the wiring substrate 102 (at 208)) can be more permanently and securely attached to the wiring substrate 102 (as compared to the attachment of the dies 112 (at 204)). FIGS. 7A-7C illustrates an example in which adhesive material 110 is applied to the die through the opening 116. As discussed above, the adhesive material 110 can be a flowable adhesive material (e.g., an epoxy), which can be poured or otherwise applied through the opening 116 such that the adhesive material 110 flows onto the die 112 and fills at least the space between the die 112 and the second surface 132 of the wiring substrate 102. The adhesive material 110 can comprise a material that sets or hardens upon contact with ambient air. Alternatively, the adhesive material 110 can comprise a material that must be cured (e.g., by heating, application of particular chemicals or gases, etc.) to cause the adhesive material 110 to set or harden. As discussed above, the adhesive material 110 can attach or secure each die 112 to the wiring substrate 102 significantly more securely (e.g., with much greater strength or adhesion) than the dam structure 120 attaches or secures each die 112 to the second surface 132 of the wiring substrate 102.

As discussed above, the dam structure 120 can limit the flow of the adhesive material 110 so that the area of the die 112 and the corresponding area of the wiring substrate 102 between which the adhesive material 110 is located can be limited to the surface area identified as 702 in FIG. 7B (which shows a bottom view). Area 702 can be referred to as the adhesive surface area 702 (which can be a non-limiting example of a limited area) and can correspond to a portion of die surface 150 of the die 112 and a corresponding portion of surface 132 of the wiring substrate 102 between which the adhesive material 110 is located. Note that in FIG. 7B the opening 116 and the dam structure 120 are shown in dashed lines because they are behind the die 112 and thus not visible.

The size of the adhesive surface area 702 can be selected depending on a number of factors or criteria. For example, the adhesive area 702 can be selected to be small compared to the die surface 150 of the die 112. (Die surface 150 can correspond to a surface area of die 112 bounded by edges 740 of the die 112.) This can allow the wiring substrate 102 and the die 112 to expand and/or contract different distances in response to the same change in temperature without breaking or otherwise damaging the bond between the die 112 and the wiring substrate 102 created by the adhesive material 110. For example, if the wiring substrate 102 and the dies 112 are made of different materials with different coefficients of thermal expansion (CTE), the wiring substrate 102 and the dies 112 can expand or contract different distances in response to the same change in temperature. The area of the adhesive area 702 (and thus the distances D₁, D₂, D₃, and D₄ and the length L and width W (see the discussion above regarding FIG. 4A)) can thus be selected to allow the dies 112 and wiring substrate 102 to expand and contract by expected distances without breaking or appreciably damaging the bond between a die 112 and the wiring substrate 102 provided by the adhesive material 110. The expected expansion and contraction distances can depend on the CTEs of the wiring substrate 102 and the dies 112 as well as other factors, such as the temperature range under which the electronics module 100 is to be operated.

Generally speaking, the smaller the ratio of the adhesive area 702 to the area of the die surface 150 of the die 112, the greater the difference in CTEs (or the greater the difference in actual expansion or contraction distances) between the wiring substrate 102 and a die 112 that can be tolerated without damaging the die 112, the wiring substrate 102, or the adhesive between the die 112 and the wiring substrate 102. In the example shown in FIG. 7B, the area of the adhesive area 702 can be equal to the following sum: A_{Total}=(L_{A}*D₂)+(L_{A}*D₄)+((W_{A}−D₂−D₄)*D₁)+((W_{A}−D₂−D₄)*D₃), where the foregoing parameters are as shown in FIG. 7B, A_{Total} is the area of the adhesive area 702, * represents multiplication, and + represents addition. In some configurations, the total area of the die surface 150 of the die 112, which can be L_{D}*W_{D} as shown in FIG. 7B, can be two, three, four, five, six, seven, eight, nine, ten, or more times greater than the total area of the adhesive area 702 A_{Total}. (The adhesive area 702 (A_{Total}) can be a non-limiting example of a limited area.)

Also generally speaking, the shorter the distances of the outer edges of the adhesive area 702 from a neutral point of the connection between a die 112 and the wiring substrate 102, the greater the difference in CTEs (or the greater the difference in actual expansion or contraction distances) between the wiring substrate 102 and a die 112 that can be tolerated without damaging the die 112, the wiring substrate 102, or the adhesive between the die 112 and the wiring substrate 102. The neutral point can be a point generally central to the physical attachment mechanisms between the die 112 and the wiring board 102 such that the neutral point does not move even as the die 112 and the wiring board 102 expand or contract at different rates. In the example shown in FIG. 7B, an exemplary neutral point 710 (which can be a non-limiting example of a center point) is shown as a point central to the adhesive area 702. Also shown are four exemplary distances X₁, X₂, Y₁, Y₂ from the neutral point 710 to an outer perimeter 742 of the adhesive area 702. In some configurations, the ratio of a distance from the neutral point 710 to edges 740 of the die 112 (edges 740 can bound die surface 150) to a corresponding distance from the neutral point 710 to an outer perimeter 742 of the adhesive area 702 can be two, three, four, five, six, seven, eight, nine, ten, or more. For example, the ratio of one half W_{D} to X₁ and/or one half W_{D} to X₂ can be two, three, four, five, six, seven, eight, nine, ten, or more. As another example, the ratio of one half L_{D} to Y₁ and/or one half W_{D} to Y₂ can be two, three, four, five, six, seven, eight, nine, ten, or more. One half W_{D} and one half L_{D} can be non-limiting examples of a distance from neutral point 710 to an edge 740 of the die 112 (or the die surface 150), and X₁, X₂, Y₁, and Y₂ can be non-limiting examples of a distance from a neutral point 710 to a perimeter (e.g., an outer perimeter) or edge of a limited area. The neutral point 710 can be a non-limiting example of a center of a limited area.

As discussed above, the shape and orientation of the area 402 shown in FIG. 4A is exemplary only, and other shapes and orientations of area 402 can be implemented. For example, area 402 need not be symmetrically oriented around opening 116. The shape and orientation of the adhesive area 702, which can be defined by the area 402, can likewise be different than shown in FIG. 7B.

As shown in FIG. 7C, a sufficient amount of the adhesive material 110 can be deposited into each opening 116 to overfill the opening 116. The adhesive material 110 can cover the terminals 114 of a die 112, the electrical connections 118, and portions of the traces 106, 124. The adhesive material 110 can thus also secure and/or protect the electrical connections 118 and the attachment of the electrical connections 118 to traces 106, 124 and terminals 114. Alternatively, the amount of the adhesive material 110 deposited into an opening 116 can be less than shown in FIG. 7C. For example, the amount of adhesive material 110 deposited into an opening 116 can be sufficient substantially only to fill the space between the wiring substrate 102 and a die 112 corresponding to the adhesive area 702 (see FIG. 7B). As yet another possible alternative, the adhesive material 110 can fill an opening 116 without overflowing the opening 116. As still another alternative, the adhesive material 110 can partially fill the opening 116. After the adhesive material 110 is deposited into the opening 116, the dam structure 120 can-but need not-be removed.

The adhesive material 110 and/or the material of the dam structure 120 can be compliant. That is, the adhesive material 110 and/or the material of the dam structure 120 can allow for some movement of the die 112 relative to the wiring substrate 102.

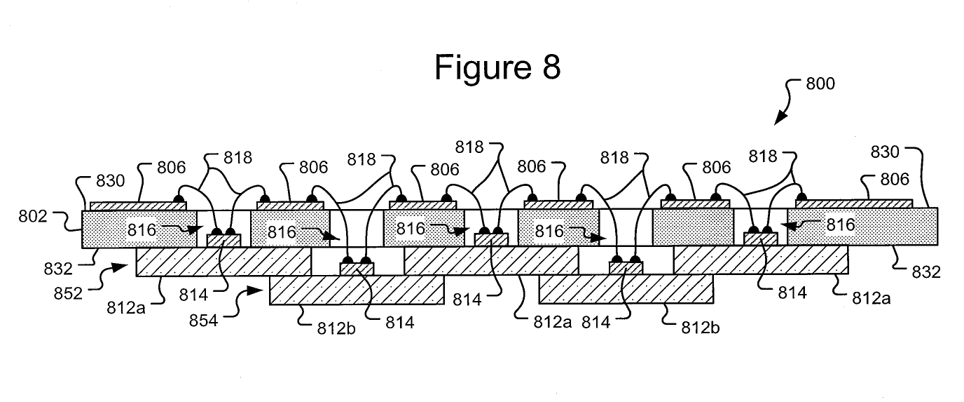

FIG. 8 illustrates a side, cross-sectional view of an exemplary electronics module 800 according to some embodiments of the invention. The electronics module 800 can be generally like the electronics module 100 of FIGS. 1A-7C except that the electronics module 800 can have multiple layers 852, 854 of attached dies 812a, 812b.

As shown in FIG. 8, electronics module 800 can include a wiring substrate 802 with electrically conductive traces 806 and openings 816. The wiring substrate 802—which, as shown in FIG. 8, can comprise a first surface 830 (which can be a non-limiting example of a layer of wiring substrate 802) and a second surface 832 (which can be a non-limiting example of a surface of wiring substrate 802)—can be the same as or similar to wiring substrate 102 of FIGS. 1A-7C. Traces 806 can be like traces 106 of FIGS. 1A-7C, and multiple traces 806 can be arranged on wiring substrate 802 in a pattern that is generally the same as or similar to the pattern of traces 106 on wiring substrate 102. In addition, although not shown in FIG. 8, wiring substrate 806 can include additional traces, for example, like traces 124 in FIGS. 1A-7C and/or any of the possible traces discussed above with respect to FIGS. 1A-7C. The dies 812a, 812b can be the same as or similar to dies 112 in FIGS. 1A-7C.

As shown in FIG. 8, dies 812a in a first layer 852 can be attached to the wiring substrate 802 with their terminals 814 disposed in or aligned with ones of the openings 816 in the wiring substrate 802. Like terminals 114, terminals 814 can be any size and can be disposed in any pattern on a die 812a, 812b. As also shown in FIG. 8, dies 812b in the second layer 854 can be attached to dies 812a in the first layer 852, or alternatively, dies 812b in the second layer 854 can be attached to the wiring substrate 802. Regardless of whether the dies 812b are attached to the dies 812a or to the wiring substrate 802, the terminals 814 of the dies 812b in the second layer 854 can be aligned with (and thus accessible through) ones of the openings 816 in the wiring substrate 802. Electrical connections 818 (which can be the same as or similar to electrical connections 118 of FIGS. 1A-7C) can electrically connect ones of traces 806 (and/or other traces not shown in FIG. 8) to ones of the terminals 914 as shown in FIG. 8.

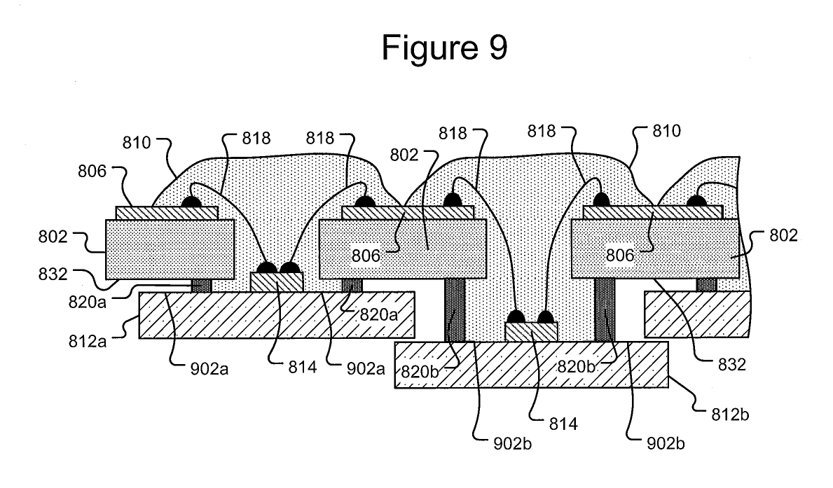

The dies 812a can be attached to the wiring substrate 802 in any manner suitable for attaching dies to a substrate. FIG. 9 illustrates a non-limiting example showing attachment of a die 812a from the first layer 852 of dies to the wiring substrate 802 in the same manner as a die 112 is attached to the wiring substrate 102 in FIGS. 1A-7C. For example, an adhesive material 810 can be deposited into an opening 816 in the wiring substrate 802. The adhesive material 810 can be like adhesive material 110 of FIGS. 1A-7C. (Adhesive material 810 can be a non-limiting example of a flowable adhesive, a second adhesive, and/or attaching a die 812a or 812b to the second surface 832 of wiring substrate 802 with a relatively strong or second adhesive strength that is stronger than a first adhesive strength.)

A dam structure 820a (which can be like dam structure 120 of FIGS. 1A-7C) can be provided between a die surface 902a of the die 812a and the second surface 832 of wiring substrate 802 and can limit the flow of the adhesive material 810 such that the areas of the die 812a and the wiring substrate 802 bonded by the adhesive material 810 are limited to an adhesive area similar to adhesive area 702 illustrated and discussed above with respect to FIGS. 7A-7C. The adhesive material 810 can overfill the opening 816 as shown in FIG. 9 and discussed above with respect to FIGS. 7A-7C. Alternatively, the adhesive material 810 can fill less than all of the opening 816 as also discussed above with respect to FIGS. 7A-7C.

In some embodiments, the dam structure 820a can comprise a material that has adhesive properties. The dam structure 820a can thus be a non-limiting example of a first adhesive material and/or attaching a die 812a to second surface 832 of wiring substrate 802 with a relatively weak or first adhesive strength. In some embodiments, dam structure 820a can be replaced with dots or droplets of material (which can be a non-limiting example of a first adhesive material) that are spaced apart from each other or in other patterns that include spaces. In such a case, the flow of adhesive material 810 over a die 812a can be controlled by means other than a dam structure. For example, the flow of adhesive material 810 over the die 812a can be controlled and limited by controlling the amount of adhesive material 810 applied into an opening 816.

The dies 812b can be attached to dies 812b using an adhesive or other suitable material to adhere portions of a die 812b to adjacent dies 812a. Alternatively, as shown in FIG. 9, dies 812b can be attached to the wiring substrate 802 in the same manner as die 812a is attached to the wiring substrate 802.

For example, as shown in FIG. 9, the adhesive material 810 can be deposited into an opening 816 in the wiring substrate 802 that corresponds to a die 812b in the second layer 854 of dies. The adhesive material 810 can be like adhesive material 110 of FIGS. 1A-7C. A dam 820b (which can be like dam structure 120 of FIGS. 1A-7C or dam 812a of FIG. 8) can be provided between a die surface 902b of the die 812b and the second surface 832 of wiring substrate 802 and can limit the flow of the adhesive material 810 such that the areas of the die 812b and the wiring substrate 802 bonded by the adhesive material 810 are limited to an adhesive area similar to adhesive area 702 illustrated and discussed above with respect to FIGS. 7A-7C. The adhesive material 810 can overfill the opening 816 as shown in FIG. 9. Alternatively, the adhesive 810 can fill less than all of the opening 816 as generally discussed above.

In some embodiments, the dam structure 820b can comprise a material that has adhesive properties. The dam structure 820b can thus be a non-limiting example of a first adhesive material and/or attaching a die 812b to second surface 832 of wiring substrate 802 with a relatively weak or first adhesive strength. In some embodiments, dam structure 820b can be replaced with dots or droplets of material (which can be a non-limiting example of a first adhesive material) that are spaced apart from each other or in other patterns that include spaces. In such a case, the flow of adhesive material 810 over a die 812b can be controlled by means other than a dam structure. For example, the flow of adhesive material 810 over the die 812b can be controlled and limited by controlling the amount of adhesive material 810 applied into an opening 816.

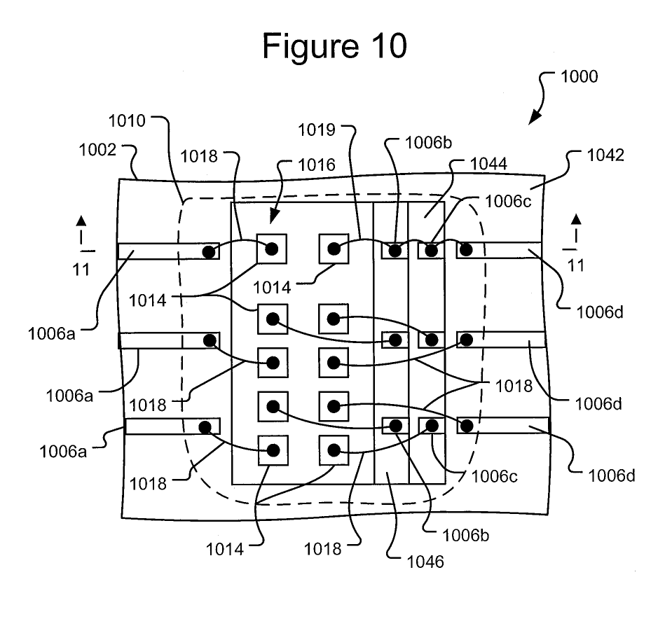

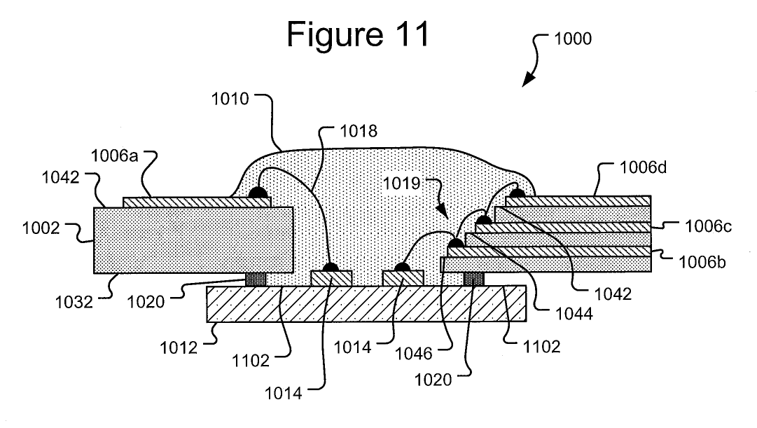

FIGS. 10 and 11 illustrate a portion of an exemplary electronics module 1000 according to some embodiments of the invention. FIGS. 10 and 11 illustrate a portion of a wiring substrate 1002, which as shown, can comprise a first surface 1042 (which can be a non-limiting example of a layer of wiring substrate 1002) and a second surface 1032 (which can be a non-limiting example of a surface of wiring substrate 1002) and can include one or more openings 1016. The wiring substrate 1002 can be generally similar to wiring substrate 102 of FIGS. 1A-7C and can include electrically conductive traces 1006a and 1006d on a first surface 1042 of the wiring substrate 1002. (Traces 1006a, 1006d can be non-limiting examples of first traces.) Also shown in FIGS. 10 and 11 are additional traces 1006b and 1006c, which can be embedded within the wiring substrate 1002. (Traces 1006b, 1006c can be non-limiting examples of second traces.) Traces 1006a, 1006b, 1006c, 1006d can be the same as or similar to traces 106, 124 of FIGS. 1A-7C. Although not shown, wiring substrate 1002 can include additional traces.

As shown in FIGS. 10 and 11, the opening 1002 can include stepped portions 1044, 1046 that expose portions (e.g., ends) of embedded traces 1006b and 1006c. (One or more of first surface 1042 and/or stepped portions 1044 and/or 1046 can be non-limiting examples of a layer of wiring substrate 1002, and traces 1006b, 1006c can be non-limiting examples of second traces.) A die 1012 (which can be the same as or similar to dies 112 of FIGS. 1A-7C) can be attached to the wiring substrate 1002 with terminals 1014 of the die 1012 disposed in or accessible through the opening 1002. Note that, although the die 1012 is illustrated in FIG. 10 with two rows of terminals 1014, die 1012 can include more or fewer rows of terminals 1014 and more or fewer terminals 1014 in each row. As another alternative, terminals 1014 can be arranged in patterns other than rows.

As also shown in FIGS. 10 and 11, electrical connections 1018 (which can be like electrical connections 118 of FIGS. 1A-8B) can be provided between ones of the terminals 1014 of the die 1012 and ones of the traces 1006a, 1006d on a first surface 1042 of the wiring substrate 1002. Electrical connections 1018 can also be provided between ones of the terminals 1014 of the die 1012 and exposed portions of ones of the embedded traces 1006b, 1006c. As also shown, an electrical connection 1019 can be made from a terminal 1014 of the die 1012 to multiple traces. For example, electrical connection 1019 is shown in FIGS. 10 and 11 electrically connecting a terminal 1014 of die 1012 to one of traces 1006b, 1006c, and 1006d. Electrical connection 1019 can comprise a single wire stitch bonded to the terminal 1014 and each of the ones of traces 1006b, 1006c, 1006d.

The die 1012 can be attached to the wiring substrate 1002 in any suitable manner including, without limitation, the methods illustrated in FIGS. 1A-9. For example, as shown in FIG. 11, a dam structure 1020 (which can comprise the same or similar material as and can be formed like dam structure 120 or dam structure 820a, 820b of FIGS. 1A-9) can be disposed between the second surface 1032 of the wiring substrate 1002 and a die surface 1102 of the die 1012 as shown in FIG. 11, and an adhesive material 1010 (which can comprise the same or similar material as and can be formed like adhesive material 110 or adhesive material 810 of FIGS. 1A-9) can be deposited in the opening 1016. (Adhesive material 1010 can be anon-limiting example of a flowable adhesive, a second adhesive, and/or attaching a die 1012 to the second surface 1032 of wiring substrate 1002 with a relatively strong or second adhesive strength that is stronger than a first adhesive strength.)

Although specific embodiments and applications of the invention have been described in this specification, there is no intention that the invention be limited to these exemplary embodiments and applications or to the manner in which the exemplary embodiments and applications operate or are described herein.

1. An electronics module comprising:
a wiring substrate having a plurality of openings therein, the wiring substrate comprising at least one layer having a plurality of traces thereon, and a surface;
a plurality of semiconductor dies each comprising a plurality of terminals;
a first adhesive material attaching with a first adhesive strength the dies to the surface of the wiring substrate;
a plurality of electrical connections through the openings electrically connecting ones of the traces with ones of the terminals; and
a second adhesive material attaching with a second adhesive strength the plurality of dies to the wiring substrate,
wherein the second adhesive strength is greater than the first adhesive strength.

2. The electronics module of claim 1, wherein the second adhesive material is disposed in the plurality of openings.

3. The electronics module of claim 2, wherein the second adhesive material overflows the plurality of openings.

4. The electronics module of claim 3, wherein the second adhesive material covers the terminals and portions of the traces at which the electrical connections are attached to the traces.

5. The electronics module of claim 2, wherein the first adhesive material comprises dam structures disposed between a die surface of each die and the surface of the wiring substrate.

6. The electronics module of claim 5, wherein each of the dam structures impedes the second adhesive material such that the second adhesive material is disposed between each die and the surface of the wiring substrate only at a limited area of the die surface of each of the dies, the limited area defined by the dam structure.

7. The electronics module of claim 6, wherein the die surface of each die is at least four times the limited area of each die.

8. The electronics module of claim 6, wherein the die surface of each die is at least ten times the limited area of each die.

9. The electronics module of claim 6, wherein a distance from a center of the limited area on each die to an edge of the die surface of the die is at least four times a distance from the center of the limited area to an outer perimeter of the limited area.

10. The electronics module of claim 6, wherein a distance from a center of the limited area on each die to an edge of the die surface of the die is at least ten times a distance from the center of the limited area to an outer perimeter of the limited area.

11. The electronics module of claim 1, wherein the second adhesive material comprises an epoxy.

12. The electronics module of claim 1, wherein the first adhesive material comprises spaced apart droplets disposed between the surface of the wiring substrate and the plurality of dies.

13. The electronics module of claim 1, wherein:
the plurality of dies comprise a first layer of dies and a second layer of dies,
the first layer of dies are disposed between the surface of the wiring substrate and the second layer of dies such that ones of the dies in the second layer partially overlap ones of the dies in the first layer.

14. The electronics module of claim 1, wherein at least one of the openings in the wiring substrate comprises a stepped portion on which ends of second traces embedded within the wiring substrate are exposed, the electronics module further comprising additional electrical connections through the at least one of the openings electrically connecting ones of the second traces with ones of the terminals.

15. An electronics module comprising:
a wiring substrate having a plurality of openings therein, the wiring substrate comprising at least one layer having a plurality of traces thereon and a surface;
a plurality of semiconductor dies each comprising a plurality of terminals disposed adjacent one of the openings;
a plurality of dam structures, each dam structure disposed between the wiring substrate and one of the dies, each dam structure surrounding one of the openings;
a plurality of electrical connections through the openings electrically connecting ones of the traces with ones of the terminals of the dies; and
an adhesive attaching the plurality of dies to the wiring substrate, wherein each of the dam structures impedes the adhesive such that the adhesive is disposed between each die and the surface of the wiring substrate only at a limited area of a die surface of each of the dies, the limited area defined by one of the dam structures.

16. The electronics module of claim 15, wherein the die surface of each die is at least four times the limited area of each die.

17. The electronics module of claim 15, wherein the die surface of each die is at least ten times the limited area of each die.

18. The electronics module of claim 15, wherein a distance from a center of the limited area on each die to an edge of the die surface of the die is at least four times a distance from the center of the limited area to an outer perimeter of the limited area.

19. The electronics module of claim 15, wherein a distance from a center of the limited area on each die to an edge of the die surface of the die is at least ten times a distance from the center of the limited area to an outer perimeter of the limited area.

20. A method of making an electronics module, the method comprising:
providing a wiring substrate having a plurality of openings therein, the wiring substrate comprising at least one layer having a plurality of traces thereon and a surface;
attaching with a first adhesive strength a plurality of semiconductor dies to the surface of the wiring substrate, each of the semiconductor dies comprising a plurality of terminals;
electrically connecting through the openings ones of the traces with ones of the terminals; and
attaching with a second adhesive strength selected ones of the plurality of dies to the surface,
wherein the second adhesive strength is greater than the first adhesive strength.

21. The method of claim 20, wherein the attaching with a second adhesive strength occurs after the electrically connecting.

22. The method of claim 20, wherein the attaching with a second adhesive strength comprises:
depositing a flowable adhesive through at least one of the plurality of openings, and curing the adhesive.

23. The method of claim 22, wherein the depositing comprises depositing the adhesive so that the adhesive overflows the at least one of the plurality of openings.

24. The method of claim 23, wherein the depositing further comprises depositing the adhesive so that the adhesive covers at least a portion of ones of the plurality of traces.

25. The method of claim 22, wherein the depositing comprises depositing the adhesive over the terminals on the selected ones of the plurality of dies.

26. The method of claim 22, wherein the attaching with a first adhesive strength comprises attaching each of the plurality of dies to the surface of the wiring substrate by dam structures disposed between a die surface of each die and the surface of the wiring substrate.

27. The method of claim 26, wherein:
each of the selected dies is attached with the second adhesive strength to the wiring substrate by the flowable adhesive, and
each of the dam structures limits flow of the flowable adhesive such that only a limited area of the die surface of each of the selected dies is attached by the flowable adhesive to the surface of the wiring substrate.

28. The method of claim 27, wherein the die surface of each die is at least four times the limited area of each die.

29. The method of claim 27, wherein the die surface of each die is at least ten times the limited area of each die.

30. The method of claim 27, wherein a distance from a center of the limited area on each die to an edge of the die surface is at least four times a distance from the center of the limited area to an outer perimeter of the limited area.

31. The method of claim 27, wherein a distance from a center of the limited area on each die to an edge of the die surface is at least ten times a distance from the center of the limited area to an outer perimeter of the limited area.

32. The method of claim 20, wherein the attaching with a first adhesive strength comprises placing spaced apart droplets of material between the surface of the wiring substrate and the selected ones of the plurality of dies.

33. The method of claim 20 further comprising testing the plurality of dies while the dies are attached with the first adhesive strength to the wiring substrate.

34. The method of claim 33, wherein the selected ones of the dies are ones of the plurality of dies that pass the testing.

35. The method of claim 33 further comprising removing one or more of the plurality of dies that fail the testing, and replacing the removed one or more of the plurality of dies with one or more new dies, the replacing comprising attaching with the first adhesive strength the one or more new dies to the surface of the wiring substrate and electrically connecting through the openings ones of the traces with ones of terminals of the one or more new dies.

36. The method of claim 35 further comprising testing the one or more of the new dies, wherein the attaching with a second adhesive strength further comprises attaching with the second adhesive strength one or more of the new dies that pass the testing to the surface of the wiring substrate.

37. The method of claim 20, wherein:
the plurality of dies comprise a first layer of dies and a second layer of dies,
the first layer of dies are disposed between the surface of the wiring substrate and the second layer of die such that ones of the dies in the second layer partially overlap ones of the dies in the first layer.

38. The method of claim 37, wherein the selected ones of the plurality of dies attached with the second adhesive strength to the surface comprise ones of the dies in the first layer and ones of the dies in the second layer.

39. The method of claim 20, wherein:
at least one of the openings in the wiring substrate comprises a stepped portion on which ends of second traces embedded within the wiring substrate are exposed, and
the electrically connecting further comprising electrically connecting ones of the terminals of at least one of the dies with ones of the ends of the second traces.

40. A method of making an electronics module, the method comprising:
providing a wiring substrate having a plurality of openings therein, the wiring substrate comprising at least one layer having a plurality of traces thereon and a surface;
positioning a semiconductor die such that terminals of the die are in proximity to one of the openings, the positioning comprising disposing a dam structure between the wiring substrate and the die, the dam structure surrounding the one of the openings;
electrically connecting through the one of the openings ones of the traces with ones of the terminals; and
depositing a flowable adhesive in the one of the opening, the dam structure limiting flow of the adhesive, the adhesive attaching the die to the wiring substrate.

41. The method of claim 40, wherein the dam structure limits flow of the flowable adhesive such that the flowable adhesive is disposed between only a limited area of a die surface of the die and the surface of the wiring substrate.

42. The method of claim 41, wherein the die surface is at least four times the limited area.

43. The method of claim 41, wherein the die surface is at least ten times the limited area.

44. The method of claim 41, wherein a distance from a center of the limited area on the die surface to an edge of the die surface is at least four times a distance from the center of the limited area to an outer perimeter of the limited area.

45. The method of claim 41, wherein a distance from a center of the limited area on the die surface to an edge of the die surface is at least ten times a distance from the center of the limited area to an outer perimeter of the limited area.

46-90. (canceled)
